(19) United States
(12) Patent Application Publication
(10) Pub. No.: US 2008/0152168 A1
(43) Pub. Date: Jun. 26, 2008

(54) Audio signal frequency range boost circuits

(76) Inventor: Anthony J. Magrath, Edinburgh (GB)

Correspondence Address: DICKSTEIN SHAPIRO LLP, 1825 EYE STREET NW, Washington, DC, 20006-5403, US

(21) Appl. No.: 11/826,510

(22) Filed: Jul. 16, 2007

(30) Foreign Application Priority Data
Dec. 21, 2006 (GB) 0625516.0

(51) Int. Cl. H03G 5/00

(52) U.S. Cl. 381/100

(57) ABSTRACT

A tone-boost circuit for boosting a range of frequencies of an input signal without “clipping” of the signal is disclosed comprising an amplifier, a limiter, having at least one pre-determined limiter threshold, a first filter and a signal adder, the signal adder adding the output of the first filter with the original input signal. Further modifications include incorporating a second filter for filtering the input signal before being added to the output of the first filter, a third filter for filtering the input signal before amplification and a dynamic implementation of the amplifier. The circuit may be implemented in analogue or digital and is particularly relevant for bass-boost audio circuits.

### BACKGROUND

The present invention relates to signal processing circuits for boosting a desired range of frequencies in an audio signal and particularly, but not exclusively, to bass-boost audio circuits which mitigate output signal distortion.

Bass-boost circuits are used to increase the level of bass, often to compensate for poor bass response in low-cost headphones and loudspeakers. A typical application of where a bass-boost circuit may be used is when a headphone is coupled to the output of an amplifier, which is powered by a single ended (i.e. a unipolar) power supply, that has a DC-blocking capacitor C in its output signal path. The blocking capacitor C and the headphone, that is, the load, resistance R_{L} act as an R-C high-pass filter with a cut-off frequency given by:

$${F}_{C} = \frac{1}{2 π {R}_{L} C}$$

As an example, for a 32Ω load resistance R_{L}, a blocking capacitor C with a capacitance of approximately 250 μF would be required to achieve a cut-off frequency F_{C} of approximately 20 Hz, which is typically the lowest audible audio frequency.

In portable audio applications such as MP3 players, mobile communications and the like, the capacitor C should be as physically small as possible so as to maintain a small overall form-factor for the portable application. This equates to using a capacitor C with a smaller value, which consequently raises the cut-off frequency F_{C}, which in turn reduces the bass level. Other non-portable audio applications such as Hi-Fi systems, In-Car Entertainment systems and the like, may also benefit, for reasons of cost for example, from using a capacitor with a smaller physical and capacitive value. One method of compensating for this type of reduced bass level is to use a bass-boost circuit.

A typical audio amplifier circuit 10 incorporating a bass-boost circuit having: a digital input signal is shown in FIG. 1; and an analogue input signal is shown in FIG. 2.

Referring to FIG. 1, a digital input signal SIN_{D} is input to the amplifier circuit 10 at an input terminal 12 of a volume controller 14. After appropriate amplification or attenuation by the volume controller 14, the signal passes to the input of a bass-boost circuit 16 before being output and then converted to an equivalent analogue signal by a digital-to-analogue converter (DAC) 18. An analogue output signal SOUT_{A} is then outputted via an amplifier 20, via capacitor C, to the load R_{L}, such as a headphone. FIG. 2 is an analogue implementation of the amplifier circuit illustrated in FIG. 1, that has an analogue input signal SIN_{A} and an analogue output signal SOUT_{A} driving the load R_{L}.

A known bass-boost circuit 22 is shown in FIG. 3. The circuit 22 uses a band-pass filter 24 and notch filter 26 in parallel. The output signal of the band-pass filter 24 is passed through a gain block 28, and added, via the adder 30, to the output signal of the notch filter 26. If the gain value K of the gain block 28 is unity, the respective output signals of the band-pass filter 24 and notch filter 26 combine to produce an output signal from the adder 30 that has a flat frequency response. If the gain value K is increased, the output signal of the band-pass filter 24 is boosted relative to the output signal of the notch filter 26, and a signal boost occurs over a passband. The amount of signal boost at the centre-frequency of the band-pass filter 24 is given by:

gain(dB)=20 log 10(K)

A known alternative bass-boost circuit 32 is shown in FIG. 4. This arrangement is similar to the bass-boost circuit 22 of FIG. 3 except there is no notch filter 26. As a result, a gain value K of zero produces a flat frequency response in the output signal of the adder 30. If however the gain K is increased, a signal boost over the passband will occur. Therefore in this alternative example, the amount of signal boost at the centre-frequency of the bandpass filter 24 is given by:

gain(dB)=20 log 10(K+1)

If either of these bass-boost circuits 22, 32 is used to boost bass frequencies, the signal SOUT_{A} at the output of the amplifier circuit 20 will begin to reach a level which exceeds the maximum signal headroom. That is to say, the total gain (given by the two respective gain equations above) plus input signal level, at a particular frequency, cannot be amplified any further due to the limits of the amplifier circuit 10. Such a scenario is known as signal “clipping”. Whenever the output signal SOUT_{A} clips, audible distortion will be introduced into the output signal SOUT_{A}, resulting in poor quality audio signals being output from the headphone or loudspeaker.

In applications where headphones are used, the output signal SOUT_{A} voltage level at typical listening levels will be below the “clipping level” voltage. However, there will be occasional peaks in output signal SOUT_{A} where the maximum signal level is exceeded, resulting in clipping and distortion. This is particularly the case when the bass signals are boosted to compensate for the use of a smaller AC coupling capacitor.

In a digital implementation of the circuits shown in FIG. 3 and FIG. 4, clipping will occur at the output of the adder 30, so the signal will already be clipped before the DAC 18 and amplifier 20.

The invention aims to provide boosting of particular frequency ranges of an audio signal whilst mitigating noise caused by “clipping” of the signals.

According to a first aspect of the present invention there is provided a signal processing circuit for boosting a desired range of frequencies in an audio signal, the circuit comprising:
an audio input enabled to receive an input signal;
an amplifier having an amplifier input, coupled to the audio input, and an amplifier output and enabled to receive and amplify signals received at the amplifier input;
a limiter having a limiter input, coupled to the amplifier output, and a limiter output, for applying a limiting function to the amplified signal;
a first filter having a filter input, coupled to the limiter output, and a filter output and enabled to filter signals received at the filter input; and
   a signal adder coupled to the filter output and the audio input and enabled to add received signals, providing a signal output.

Preferably, the first filter is a bandpass filter, the bandpass filter having a pre-determined centre frequency.

Preferably, the bandpass filter attenuates frequencies of substantially three times the centre frequency, such that those attenuated frequencies are substantially inaudible during audio playback.

Preferably, the bandpass filter has a centre frequency between 50 Hz and 100 Hz and a bandwidth between 50 Hz and 100 Hz.

Alternatively, the filter is a low-pass filter.

Preferably, a second filter is coupled between the audio input and the signal adder in parallel to the amplifier, limiter and first filter.

Preferably, wherein the second filter is a notch filter.

Alternatively, wherein the second filter is a high-pass filter.

Preferably, the limiting function limits the amplitude of the amplified signal to within a threshold in the range 0.6 to 0.95 of full scale.

Preferably, the circuit further comprises a pre-filter coupled between the audio input and the amplifier.

Preferably, the pre-filter has substantially the same bandwidth and centre frequency as that of the first filter.

Preferably, said amplifier comprises a static gain stage.

Preferably, said amplifier comprises at least one variable gain stage.

Preferably, the circuit further comprises a control circuit for varying the gain of the variable gain stage automatically in response to actual signal levels.

Preferably, the control circuit comprises a detector for detecting a signal level at the amplifier output for comparison with at least one pre-determined threshold.

Preferably, the control circuit is arranged to reduce the gain of the variable gain stage, if the signal level detected by the detector is above the at least one pre-determined threshold.

Preferably, the control circuit is arranged to increase the gain of the variable gain stage, if the signal level detected by the detector is below the at least one pre-determined threshold.

Preferably, the control circuit further comprises a ramp means enabled to vary the gain of the variable gain stage at a pre-determined rate in response to the comparison of the signal level and the pre-determined threshold.

Preferably, the gain of the variable gain stage is reduced by the ramp means, when required, at a pre-determined attack rate.

Preferably, the pre-determined attack rate is between 10 μs/dB and 500 ms/dB.

Preferably, the pre-determined attack rate is in the range 100 to 400 ms/dB

Preferably, the gain of the variable gain stage is increased by the ramp means, when required, at a pre-determined decay rate.

Preferably, the pre-determined decay rate is between 10 ms/dB and 5 s/dB.

Preferably, the pre-determined decay rate is in the range 500 ms/dB-2 s/dB.

Alternatively, the control circuit varies the gain of the variable gain stage using pre-defined values derived from a plurality of gain curves, the control circuit arranged to compare the signal level detected by the detector and the at least one pre-determined threshold and select one of the plurality of gain curves, dependent on the static gain, and vary the gain of the variable gain stage accordingly.

Preferably, the detector is a peak signal detector.

Alternatively, the detector is a peak RMS signal detector.

Preferably, if the signal is below a threshold set by the limiting function, the gain of the variable gain stage is automatically switched into a second decay rate, which is faster than the first decay rate, by the control circuit.

Preferably, the control circuit maintains the second decay rate until the signal level reaches the threshold set by the limiting function.

Preferably, if the gain of the variable gain stage reaches the static gain, the first decay rate is again selected.

According to a second aspect of the invention there is provided a signal processing means comprising: audio input means for receiving an input signal; amplification means for amplifying the input signal and providing an amplified signal; limiting means for limiting the amplified signal by applying a limiting function and providing a limited signal; first filtering means for filtering the limited signal; and adding means coupled to the first filtering means and audio input means and for adding received signals and providing a signal output.

According to a third aspect of the invention there is provided a method of processing signals for boosting a desired range of frequencies in an audio signal, comprising: amplifying the, or a derivative of, the input signal and providing an amplified signal; limiting the amplified signal by applying a limiting function and providing a limited signal; filtering the limited signal providing a first filtered signal; and adding the first filtered signal to, or a derivative of, the input signal providing a signal output.

Preferably, the step of filtering the limited signal comprises applying a bandpass filter to the limited signal, the bandpass filter having a pre-determined centre frequency.

Preferably, the bandpass filter attenuates frequencies of substantially three times the centre frequency, such that those attenuated frequencies are substantially inaudible during audio playback.

Preferably, the bandpass filter has a centre frequency between 50 Hz and 100 Hz and a bandwidth between 50 Hz and 100 Hz.

Alternatively, the step of filtering the limited signal comprises applying a low-pass filter to the limited signal.

Preferably, the step of filtering the input signal providing a second filtered signal and the step of adding comprises adding the second filtered signal, which is a derivative of the input signal to the first filtered signal.

Preferably, the second filter is a notch filter.

Alternatively, the second filter is a high-pass filter.

Preferably, the limiting function limits the amplitude of the amplified signal to within the range of 0.6 to 0.95 of full scale.

Preferably, the method further comprises the step of pre-filtering the input signal, providing a pre-filtered signal for the step of amplifying.

Preferably, the step of filtering the input signal to provide a pre-filtered signal utilises a filter response having substantially the same bandwidth and centre frequency as that of the step of filtering the limited signal to provide a first filtered signal.

Preferably, wherein the step of amplifying comprises providing variable gain amplification.

Preferably, the step of amplifying further comprises controlling the variable gain amplification automatically in response to actual signal levels.

Preferably, the step of controlling further comprises detecting a signal level at the output of the amplifying step for comparison with at least one pre-determined threshold.

Preferably, if the signal level detected is above the at least one pre-determined threshold, the gain of the variable gain amplification is reduced.

Preferably, if the signal level detected is below the at least one pre-determined threshold, the gain of the variable gain amplification is increased.

Preferably, the gain of the variable gain amplification is varied by ramping through a set of gain settings, the gain being varied at a pre-determined rate in response to the comparison of the signal level and the pre-determined threshold.

Preferably, the gain of the variable gain amplification is reduced, when required, at a pre-determined attack rate.

Preferably, the pre-determined attack rate is between 10 μs/dB and 500 ms/dB.

Preferably, the pre-determined attack rate is 100 to 400 ms/dB

Preferably, the gain of the variable gain amplification is increased, when required, at a pre-determined decay rate.

Preferably, the pre-determined decay rate is between 100 ms/dB and 5 s/dB.

Preferably, the pre-determined decay rate is 500 ms/dB-2 s/dB.

Alternatively, the gain of the variable gain amplification is varied using pre-defined values derived from a plurality of gain curves, the gain being varied in accordance with comparison of the signal level and the at least one pre-determined threshold and selecting one of the pre-defined gain curves, dependent on the static gain, and varying the gain of the variable gain amplification accordingly.

Preferably, the step of detecting the signal level comprises detecting a peak signal.

Alternatively, the step of detecting the signal level comprises detecting a peak RMS signal.

The invention for example also provides audio apparatus including a signal processing circuit according to the invention set forth above.

The audio apparatus may be portable.

The audio apparatus may be an in-car audio apparatus, a headphone or a stereo headphone apparatus or a communications apparatus such as a mobile phone or PDA.

The audio apparatus may further include an audio output transducer, such as a speaker, connected as a load connected to an output terminal of the signal processing circuit.

These and other features and advantages of the invention in its various embodiments will be understood from a consideration of the detailed description which follows.

### BRIEF DESCRIPTION OF THE DRAWINGS

Embodiments of the invention will now be described, by way of example only, by reference to the accompanying drawings, in which:

FIG. 1 illustrates a digital-input audio circuit in which the present invention may be incorporated;

FIG. 2 illustrates an analogue-input audio circuit in which the present invention may be incorporated;

FIG. 3 illustrates a prior art digital bass-boost circuit comprising a band-pass filter and a notch filter;

FIG. 4 illustrates a prior art digital bass-boost circuit comprising only a band-pass filter;

FIG. 5 illustrates a first embodiment of the present invention comprising a first filter;

FIG. 6 illustrates a second embodiment of the present invention incorporating a second filter in parallel with the first filter;

FIG. 7 illustrates a third embodiment of the present invention incorporating a third filter in series with the first filter;

FIG. 8 illustrates a fourth embodiment of the present invention incorporating a dynamic gain control;

FIG. 9 illustrates one implementation of a dynamic gain control in the form of a feedback dynamic range control circuit;

FIG. 10 illustrates an alternative implementation of a dynamic gain control in the form of a feed-forward dynamic range control circuit;

FIG. 11 illustrates examples of appropriate gain curves for use with the feedforward dynamic range control circuit; and

FIG. 12 illustrates a frequency response graph of an embodiment including dynamic gain control.

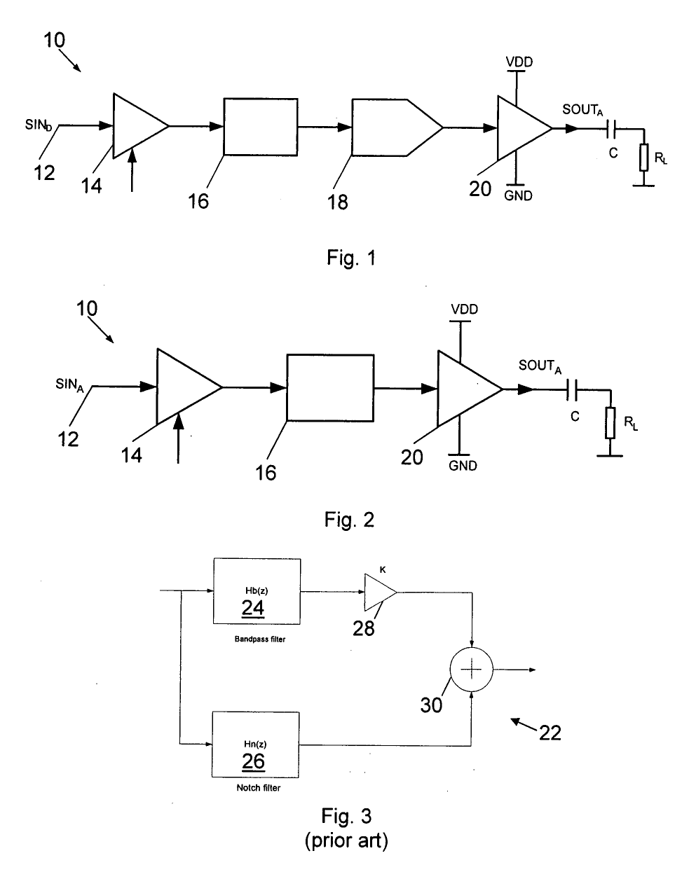

### DETAILED DESCRIPTION OF THE EMBODIMENTS

The present invention allows an increase in the level of certain frequency ranges of audio signals to be produced for typical listening levels, whilst mitigating the audible distortion due to clipping at high output signal levels. This is particularly applicable to bass frequencies and the remaining description describes, by way of example, bass-boost circuits.

Referring to FIG. 5, a bass-boost circuit 34 is shown according to a first embodiment of the present invention. The circuit 34 comprises an audio signal input terminal 36 which is split into two parallel branches. In one branch, the audio signal input terminal 36 is connected to the input of an amplifier 38. The bass-boost circuit 34 is an analogue implementation but could equally be implemented in digital. In a digital implementation, the amplifier 38 would be realised by a digital gain block. The output of the amplifier 38 is connected to the input of a limiter 40 and the output of the limiter 40 is connected to the input of a filter 42. An input of a signal adder 44 is connected to the output of the filter 42 and, in this particular embodiment, another input of the adder is connected, via the other branch, to the audio signal input terminal 36.

An audio signal S_{IN} received at the audio signal input terminal 36 of the bass-boost circuit 34 is amplified by the amplifier 38 before being passed to the limiter 40. It should be noted that, although amplifier 38 is shown as a variable gain amplifier 38, its gain will typically be set by a user of the system and, as such, is effectively a static gain. If the level, or amplitude, of the amplified audio signal S₁ exceeds a pre-determined limiter threshold, in either the positive or negative direction, the signal S₂ at the output of the limiter 40 will “clip”, which means that it is prevented from exceeding the pre-determined limiter threshold. While the following description refer to signals varying in both positive and negative directions about a ground reference, the skilled reader will appreciate that in practice the ground reference may be zero volts or a different voltage. Where the circuit operates from a single-ended supply, for example, the ground reference will usually be the mid-level between zero volts and a unipolar supply voltage.

When the signal S₂ is clipped, odd-order harmonics of the frequency of the input audio signal S₁ will be generated and appear in the resultant output signal S₂ of the limiter 40. In this embodiment, the filter 42 is a band-pass filter, which is selected such that odd-order harmonics within the signal S₂ generated by the limiter 40 will be attenuated to the extent that they are, or are substantially, inaudible in the output signal S₃ of the filter 42. Due to the increasing attenuation of the filter 42 with increasing frequency, higher order harmonics, which are more objectionable in terms of sound quality, will have increasing levels of attenuation.

Typically, when the filter 42 is a band-pass filter, it will have a centre frequency between 50 Hz and 100 Hz and a bandwidth between 50 Hz and 100 Hz. Ideally, the filter bandwidth is chosen so that signals of 3-times the centre-frequency (corresponding to the third-harmonic of the amplified input signal S_{IN}) and above are well attenuated.

The signal adder 44 then adds signal S₃ and S_{IN} to produce output signal S_{OUT}.

Referring now to FIG. 6, a bass-boost circuit 46 is shown according to a second embodiment of the present invention. The circuit 46 is similar to the bass-boost circuit 34 shown in FIG. 5 in that it comprises an audio signal input terminal 48 which is split into two parallel branches. In one branch, the audio signal input terminal 48 is connected to the input of an amplifier 50 (again, if it is a digital implementation then the amplifier 50 would be realised by a digital gain block), the output of the amplifier 50 is connected to the input of a limiter 52 and the output of the limiter 52 is connected to the input of a filter 54, which in this embodiment is a band-pass filter 54. An input of a signal adder 56 is connected to the output of the filter 54. Limiter 52 implements a limiting function which, in the simplest example, merely clips the signal to prevent it going beyond a predetermined threshold value, either in the positive or negative direction. This threshold will be referred to as the limiting threshold S_{T}.

In this embodiment, the other branch comprises a second filter 58 with an input connected to the audio signal input terminal 48 and an output terminal connected to another input terminal of the adder 56. The second filter 58 is, in this particular embodiment, a notch filter, which filters out of the signal frequencies between a pre-defined range of frequencies to produce audio signal S₄. As such, when the respective output signals S₄ and S₃ from the notch filter 58 and the band-pass filter 54 are combined by the adder 56 to generate the output signal S_{OUT} of the bass-boost circuit 46, the full range of frequencies are outputted in the output signal S_{OUT} but with an amplified, or boosted, bass range.

In both of the above embodiments shown in FIGS. 5 and 6, it is possible to amplify the signal level within the respective ranges of the respective band-pass filters 42, 54 that are above the pre-determined respective limiter 40, 52 thresholds without introducing any, or any significant, audible distortion. When a notch filter 58 is present, as in the second embodiment (FIG. 6), the respective limiter 52, when it is a clipping type limiter, typically has the pre-determined limiter threshold S_{T} set to a fraction, for example +/−0.75, of the full-scale input signal level. Preferably, S_{T} is between 0.6 to 0.95 of full scale. This allows for sufficient headroom such that when the filtered signal S₃ outputted from the filter 54 is added by the adder 56 to the output of the notch filter 46, the final output signal S_{OUT} does not clip further. This prevents the further generation of harmonic distortion which is not filtered and would therefore be clearly audible. When the notch filter 58 is not present, as in the first embodiment (FIG. 5), a lower limiter threshold S_{T} is required in comparison with the second embodiment (FIG. 6), since the signal path between the input terminal 36 and the adder 44 has the full signal bandwidth and the summed output signals S_{IN} and S₃ would have a greater amplitude.

The respective band-pass filters 42, 54 and notch filter 58 used in the embodiments of FIGS. 5 and 6 can be respectively replaced with low-pass and high-pass filters (not illustrated) if a “shelving filter” response is required, rather than a band-pass response, at the outputs of the bass-boost circuits 34, 46. In the context of a bass-boost circuit (34, 46), the shelving filter has the disadvantage that very low frequencies (below 20 Hz for example) are boosted which subsequently cannot be reproduced by the headphones or speakers and may increase the possibility of overload. Therefore, in most applications the band-bass filters 42, 54 and notch filter 58 are preferred. In addition, the example embodiments of FIGS. 5 and 6 are shown using digital type filters and associated circuitry, but may equally be implemented as analogue type filters and associated circuitry or as an operative mixture of both.

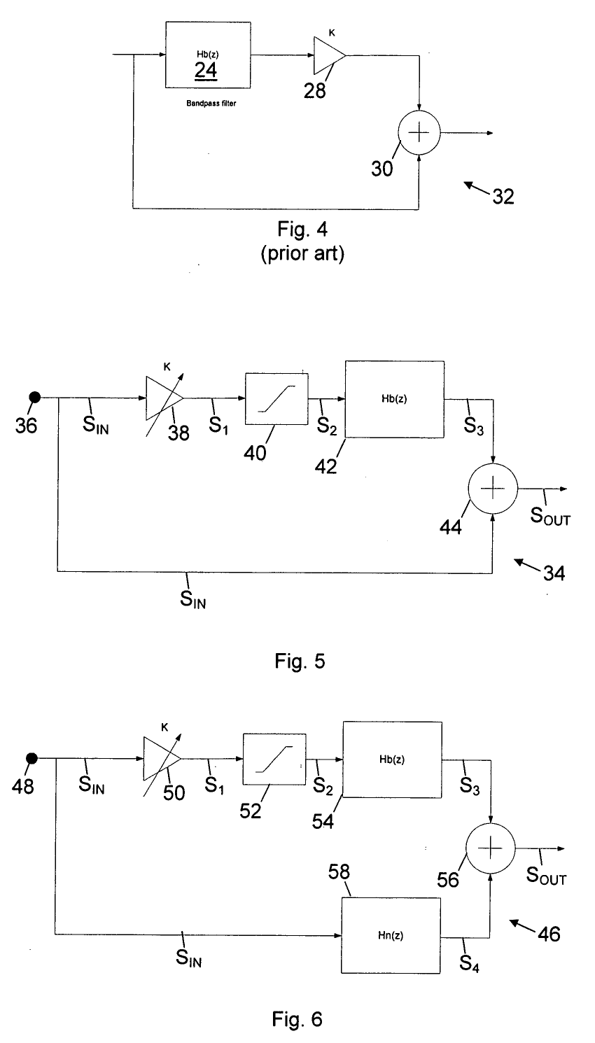

One potential problem with the circuit of FIG. 5 or 6 is that signals which are outside the range of the bandpass filter, may be clipped by the limiter but not be boosted overall by the circuit. This means that distortion is introduced which is not present in the prior-art FIGS. 3 and 4.

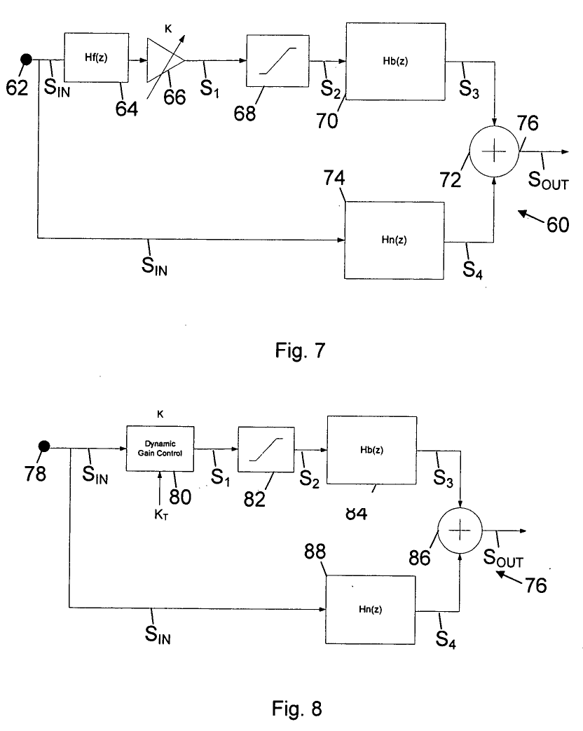

A third embodiment of the present invention, which mitigates this potential problem, is shown in FIG. 7. Referring to FIG. 7, a bass-boost circuit 60 comprises an audio signal input terminal 62 which is split into two parallel branches. In one branch, the audio signal input terminal 62 is connected to the input terminal of a third filter 64, the output terminal of the third filter is connected to the input terminal of an amplifier 66, the output terminal of the amplifier 66 is connected to the input terminal of a limiter 68 and the output terminal of the limiter 68 is connected to the input terminal of a first filter 70. The output terminal of the first filter 70 is connected to a first input terminal of a signal adder 72. The other branch comprises a second filter 74 having an input terminal connected to the audio signal input terminal 62. The output terminal 76 of the adder 72 outputs the output signal S_{OUT} of the bass-boost circuit 60. The third filter 64 removes frequencies from the input signal S_{IN} appearing on the input terminal 62 which are outside the range of the first filter 70. This prevents frequencies outside the range of the first filter 70, which are not being boosted overall, from being clipped by the limiter 68, which further reduces any distortion in the signal caused by harmonics.

As described in previous embodiments, the first and second filters, respectively 70 and 74, in the embodiment of FIG. 7 may be respectively band-pass and notch filters or respectively low-pass and high-pass filters. The notch filter 74 may also be eliminated entirely, as described in relation to the first embodiment (FIG. 5).

A fourth embodiment of the present invention is shown in FIG. 8. In this embodiment, a bass-boost circuit 76 comprises an audio signal input 78 which is split into two parallel branches. In one branch, the audio signal input terminal 78 is connected to the input terminal of a dynamic gain controller 80, having both a static gain and a variable gain, and the output terminal of the gain controller 80 is connected to the input terminal of a limiter 82 whose output terminal is connected to the input terminal of a first (bandpass) filter 84. The output terminal of the first filter 84 is connected to a first input terminal of a signal adder 86. The other branch comprises a second (notch) filter 88 with an input connected to the audio signal input terminal 78 and an output connected to a second input terminal of the adder 86. The output terminal of the adder 86 outputs the output signal S_{OUT} of the bass-boost circuit 76.

In this fourth embodiment, the static gain control provided by amplifiers 38, 50, 66 of the previous three embodiments is replaced by a dynamic gain controller 80 that is capable of providing both variable and static gain control. The dynamic gain controller 80 prevents signal distortion by automatically reducing its gain if the level of the input signal S_{IN} that is boosted by its static gain setting exceeds a predefined threshold. The programmable static gain represents the target gain of the bass boost circuit, set, for example, by the user.

The dynamic gain controller 80 can replace amplifiers, or gain blocks, if implemented digitally, 38, 50, 66 of any of the previous three embodiments. Several methods for implementing the dynamic range control are possible.

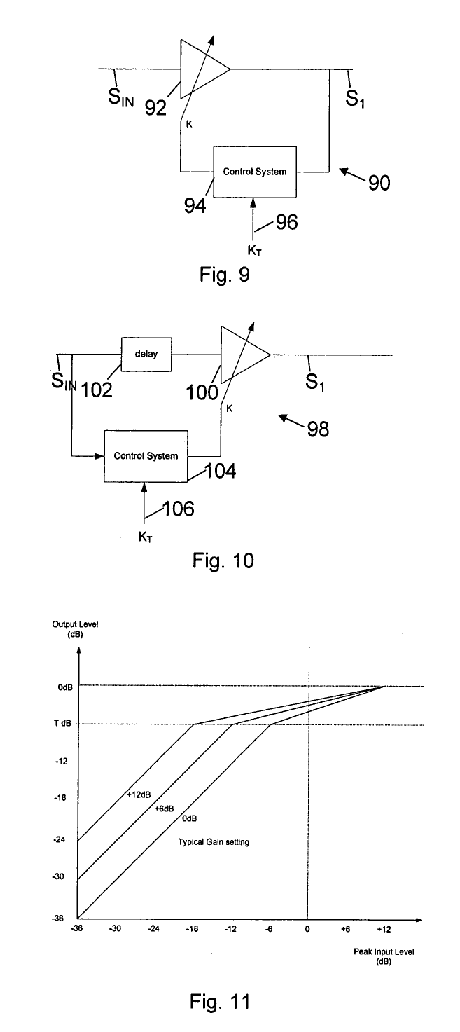

For example, as shown in FIG. 9, a feedback dynamic range control circuit 90 comprises a variable amplifier or gain control 92, a control system 94 and a static gain input 96. The control system 94 firstly estimates the signal level at the output of the variable amplifier 92 using a peak detector (not illustrated). If the peak signal level is above a predetermined threshold (K_{T}), the gain K is reduced at a specified attack rate using, for example, a counter circuit (not illustrated) which ramps through a set of gain settings. If the signal level is below the threshold K_{T}, the gain K is increased at a specified decay rate until it reaches either the static gain level as set by the user, or the threshold level K_{T}. The threshold level K_{T} is set such that clipping of the output signal of the adder 86 is just avoided. The use of a long decay-time Td (e.g. 100 ms/dB gain change) and fast attack time Ta (e.g. 200 μs/dB gain change), i.e. Td>>Ta, allows the bass-boost circuit 76 to respond quickly to a sudden increase in input signal level, but without causing the gain K to fluctuate if a low frequency signal is applied. If the signal clips temporarily before the gain is reduced adequately, the clipping will not be audible in any case due to the first filter 84.

Alternatively, as shown in FIG. 10, a feed-forward dynamic range control circuit 98 comprises a variable amplifier or gain control stage 100, optional delay 102 circuitry, a control system 104 and a static gain control input 106. The signal level at the input of the variable amplifier 100 is estimated by using a peak-detector (not illustrated) so as to estimate the input signal level, then modifying this level according to the current static gain setting. If the estimated signal level is above a defined threshold level, the output level is reduced according to a defined gain curve. Effectively, there are a set of gain curves, one for every static gain setting. Examples of gain curves are shown in FIG. 11. According to the peak input signal value obtained from the peak-detector, an appropriate gain setting can be selected from a series of settings as illustrated by the graphs. As with the feedback dynamic range control circuit 90, the gain decrease and increase is controlled with defined attack and decay rates.

If the dynamic (variable) gain has been reduced by the gain control stage 100 due to a previous signal occurring above the limiter threshold, and, for example, following this a user reduces the input gain 106, the dynamic gain will increase at a rate set by the decay rate, until either the static gain is reached or the signal level reaches the threshold.

Due to the slow rate of decay, the user may potentially experience a gradual increase in bass level which may not sound acceptable. Therefore, to mitigate this potential problem, when the input gain is reduced, and if the signal is below the limiter threshold, the dynamic gain automatically switches into a faster decay rate. This faster decay rate is maintained until either the signal level reaches the limiter threshold, or the gain reaches the static gain, after which the slower decay rate is again selected.

It will be appreciated by those skilled in the art that that in both embodiments of the control circuits 90 and 98 that an RMS type detector, or other type of signal detector, may be used instead of the peak-detector.

It will be further appreciated by those skilled in the art that any implementation may be carried out by using digital signals and circuits or analogue signals or circuits or indeed a mixture of both analogue and digital signals and circuits.

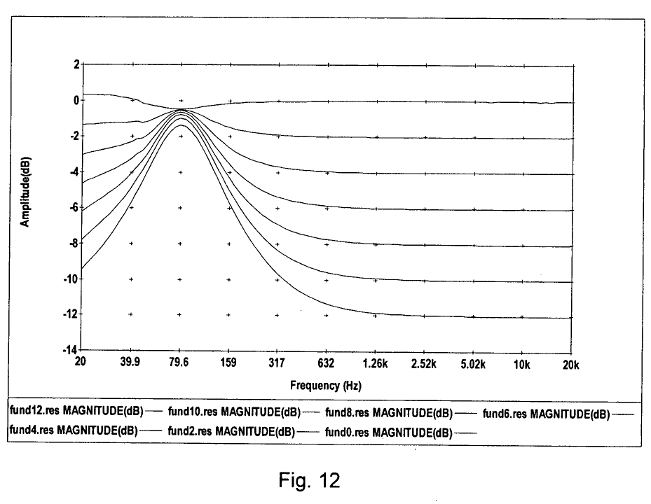

FIG. 12 shows an example of the obtainable frequency response with a bass-boost circuit using dynamic gain control. As can be seen, bass frequencies at low amplitude levels are boosted significantly (up to the user defined static gain setting), whereas bass frequencies at high amplitude levels may even be decreased to avoid clipping.

It should be noted that where a claim recites that elements are “coupled”, this is not to be interpreted as requiring direct coupling to the exclusion of any other element, but rather the elements are coupled or connected sufficient to enable those elements to function as described. The skilled reader will appreciate that a good, practical design might include many auxiliary components not mentioned here, performing, for example, start-up and shutdown functions, sensing functions, fault protection or the like, none of which detract from the basic functions characteristic of the invention in its various embodiments described above and in the claims.

In addition, although the invention is described in relation to a single audio signal or channel, it can be also applied to multiple channels, such as left and right channels of headphones or surround sound type systems. Furthermore, where the invention is applied to a plurality of audio signals or channels, some elements may provide common functions to those plurality of signals/channels. For example, the dynamic gain control may apply a common gain to more than one audio signal but each audio signal has an individual band-pass filter.

The response of the human ear is such that distortions at higher frequencies are more perceptible than distortions at lower frequencies. As alluded to above, circuits such as those described with reference to FIGS. 5 to 12 may be applicable to frequency ranges other than bass frequencies. The relevant bass frequencies are believed to be up to approximately 300 Hz, as applying the circuits to frequencies higher than that introduces harmonics or distortions at higher frequencies, which will be more perceptible to the human ear. With that in mind, these circuits can, therefore, be applied to a high frequency range in which the harmonics generated are above the human audible range. As such, the circuits have wider application than just for bass-boost circuits.

Furthermore, the above described embodiments illustrate rather than limit the invention, and that those skilled in the art will be able to design many alternative embodiments without departing from the spirit or scope of the appended claims and drawings. The word “comprising” does not exclude the presence of elements or steps other than those listed in a claim, “a” or “an” does not exclude a plurality, and a single element may fulfil the functions of several elements recited in the claims. It should also be noted that the attenuation, or decrease, of a signal amplitude is a form of amplification, thus the word “amplify”, amplifying”, “amplified” and the like can be taken to mean an increase or a decrease in the amplitude of a signal. Similarly any reference to “gain” applied may refer to a gain less than unity being applied (that is the effect of applying “gain” to a signal may result in its attenuation). The terms “gain” and “amply” are intended to be interchangeable. Also any reference to “addition”, “add” or “adding” may equally mean subtraction. Any reference signs in the claims shall not be construed so as to limit their scope.

What is claimed is:

1. A signal processing circuit for boosting a desired range of frequencies in an audio signal, the circuit comprising:
an audio input enabled to receive an input signal;
an amplifier having an amplifier input, coupled to the audio input, and an amplifier output and enabled to receive and amplify signals received at the amplifier input;
a limiter having a limiter input, coupled to the amplifier output, and a limiter output, for applying a limiting function to the amplified signal;
a first filter having a filter input, coupled to the limiter output, and a filter output and enabled to filter signals received at the filter input; and
a signal adder coupled to the filter output and the audio input and enabled to add received signals, providing a signal output.

2. A circuit as claimed in claim 1, wherein the first filter is a bandpass filter, the bandpass filter having a pre-determined centre frequency.

3. A circuit as claimed in claim 2, wherein the bandpass filter attenuates frequencies of substantially three times the centre frequency, such that those attenuated frequencies are substantially inaudible during audio playback.

4. A circuit as claimed in claim 2, wherein the bandpass filter has a centre frequency between 50 Hz and 100 Hz and a bandwidth between 50 Hz and 100 Hz.

5. A circuit as claimed in claim 1, wherein the filter is a low-pass filter.

6. A circuit as claimed in claim 1, wherein a second filter is coupled between the audio input and the signal adder in parallel to the amplifier, limiter and first filter.

7. A circuit as claimed in claim 6, wherein the second filter is a notch filter.

8. A circuit as claimed in claim 6, wherein the second filter is a high-pass filter.

9. A circuit as claimed in claim 1, wherein the limiting function limits the amplitude of the amplified signal to within a threshold in the range 0.6 to 0.95 of full scale.

10. A circuit as claimed in claim 1, further comprising a pre-filter coupled between the audio input and the amplifier.

11. A circuit as claimed in claim 10, wherein the pre-filter has substantially the same bandwidth and centre frequency as that of the first filter.

12. A circuit as claimed in claim 1, wherein said amplifier comprises a static gain stage.

13. A circuit as claimed in claims 1, wherein said amplifier comprises at least one variable gain stage.

14. A circuit as claimed in claim 13, further comprising a control circuit for varying the gain of the variable gain stage automatically in response to actual signal levels.

15. A circuit as claimed in claim 14, wherein the control circuit comprises a detector for detecting a signal level at the amplifier output for comparison with at least one pre-determined threshold.

16. A circuit as claimed in claim 15, wherein the control circuit is arranged to reduce the gain of the variable gain stage, if the signal level detected by the detector is above the at least one pre-determined threshold.

17. A circuit as claimed in claim 15, wherein the control circuit is arranged to increase the gain of the variable gain stage, if the signal level detected by the detector is below the at least one pre-determined threshold.

18. A circuit as claimed in claim 16, wherein the control circuit further comprises a ramp means enabled to vary the gain of the variable gain stage at a pre-determined rate in response to the comparison of the signal level and the pre-determined threshold.

19. A circuit as claimed in claim 18, wherein the gain of the variable gain stage is reduced by the ramp means, when required, at a pre-determined attack rate.

20. A circuit as claimed in claim 19, wherein the pre-determined attack rate is between 10 μs/dB and 500 ms/dB.

21. A circuit as claimed in claim 19, wherein the pre-determined attack rate is in the range 100 ms/dB to 400 ms/dB

22. A circuit as claimed in claim 17, wherein the gain of the variable gain stage is increased by the ramp means, when required, at a pre-determined first decay rate.

23. A circuit as claimed in claim 22, wherein the pre-determined first decay rate is between 100 ms/dB and 5 s/dB.

24. A circuit as claimed in claim 22, wherein the pre-determined first decay rate is in the range 500 ms-2 s/dB.

25. A circuit as claimed in claim 15, wherein the control circuit varies the gain of the variable gain stage using a plurality of pre-defined gain curves, the control circuit arranged to compare the signal level detected by the detector and the at least one pre-determined threshold and select one of the plurality of gain curves, dependent on the static gain, and vary the gain of the variable gain stage accordingly.

26. A circuit as claimed in claim 15, wherein the detector is a peak signal detector.

27. A circuit as claimed in claim 15, wherein the detector is a peak RMS signal detector.

28. A circuit as claimed in claim 22, wherein, if the signal is below a threshold set by the limiting function, the gain of the variable gain stage is automatically switched into a second decay rate, which is faster than the first decay rate, by the control circuit.

29. A circuit as claimed in claim 28, wherein, the control circuit maintains the second decay rate until the signal level reaches the threshold set by the limiting function.

30. A circuit as claimed in claim 28, wherein, if the gain of the variable gain stage reaches the static gain, the first decay rate is again selected.

31. A signal processing means comprising: audio input means for receiving an input signal; amplification means for amplifying the input signal and providing an amplified signal; limiting means for limiting the amplified signal by applying a limiting function and providing a limited signal; first filtering means for filtering the limited signal; and adding means coupled to the first filtering means and audio input means and for adding received signals and providing a signal output.

32. A method of processing signals for boosting a desired range of frequencies in an audio signal, comprising: amplifying the, or a derivative of, the input signal and providing an amplified signal; limiting the amplified signal by applying a limiting function and providing a limited signal; filtering the limited signal providing a first filtered signal; and adding the first filtered signal to, or a derivative of, the input signal providing a signal output.

33. A method as claimed in claim 32, wherein the step of filtering the limited signal comprises applying a bandpass filter to the limited signal, the bandpass filter having a pre-determined centre frequency.

34. A method as claimed in claim 33, wherein the bandpass filter attenuates frequencies of substantially three times the centre frequency, such that those attenuated frequencies are substantially inaudible during audio playback.

35. A method as claimed in claim 33, wherein the bandpass filter has a centre frequency between 50 Hz and 100 Hz and a bandwidth between 50 Hz and 100 Hz.

36. A method as claimed in claim 32, wherein the step of filtering the limited signal comprises applying a low-pass filter to the limited signal.

37. A method as claimed in claim 32 further comprising the step of filtering the input signal providing a second filtered signal and the step of adding comprises adding the second filtered signal, which is a derivative of the input signal to the first filtered signal.

38. A method as claimed in claim 37, wherein the second filter is a notch filter.

39. A method as claimed in claim 37, wherein the second filter is a high-pass filter.

40. A method as claimed in claim 32, wherein the limiting function limits the amplitude of the amplified signal to within the range of 0.6 to 0.95 of full scale.

41. A method as claimed in claim 32 further comprising the step of pre-filtering the input signal, providing a pre-filtered signal for the step of amplifying.

42. A method as claimed in claim 41, wherein the step of filtering the input signal to provide a pre-filtered signal utilises a filter response having substantially the same bandwidth and centre frequency as that of the step of filtering the limited signal to provide a first filtered signal.

43. A method as claimed in claim 32, wherein the step of amplifying comprises providing variable gain amplification.

44. A method as claimed in claim 43, wherein the step of amplifying further comprises controlling the variable gain amplification automatically in response to actual signal levels.

45. A method as claimed in claim 44, wherein the step of controlling further comprises detecting a signal level at the output of the amplifying step for comparison with at least one pre-determined threshold.

46. A method as claimed in claim 45, wherein, if the signal level detected is above the at least one pre-determined threshold, the gain of the variable gain amplification is reduced.

47. A method as claimed in claim 45, wherein, if the signal level detected is below the at least one pre-determined threshold, the gain of the variable gain amplification is increased.

48. A method as claimed in claim 46, wherein the gain of the variable gain amplification is varied by ramping through a set of gain settings, the gain being varied at a pre-determined rate in response to the comparison of the signal level and the pre-determined threshold.

49. A method as claimed in claim 48, wherein the gain of the variable gain amplification is reduced, when required, at a pre-determined attack rate.

50. A method as claimed in claim 49, wherein the pre-determined attack rate is between 10 ms/dB and 5000 ms/dB.

51. A method as claimed in claim 49 or 50, wherein the pre-determined attack rate is 50 to 100 ms/dB

52. A method as claimed in claim 47, wherein the gain of the variable gain amplification is increased, when required, at a pre-determined decay rate.

53. A method as claimed in claim 52, wherein the pre-determined decay rate is between 10 μs/dB and 10000 μs/dB.

54. A method as claimed in claim 52, wherein the pre-determined decay rate is 100-400 μs/dB.

55. A method as claimed in claim 45, wherein the gain of the variable gain amplification is varied using pre-defined values derived from a plurality of gain curves, the gain being varied in accordance with comparison of the signal level and the at least one pre-determined threshold and selecting one of the pre-defined gain curves, dependent on the static gain and varying the gain of the variable gain amplification accordingly.

56. A method as claimed in claim 45, wherein the step of detecting the signal level comprises detecting a peak signal.

57. A method as claimed in claim 45, wherein the step of detecting the signal level comprises detecting a peak RMS signal.

58. A method as claimed in claim 52, wherein if the signal is below a threshold set by the limiting function, the gain of the variable gain stage is automatically switched into a second decay rate, which is faster than the first decay rate.

59. A method as claimed in claim 58, wherein the second decay rate is maintained until the signal level reaches the threshold set by the limiting function.

60. A method as claimed in claim 58, wherein if the gain of the variable gain stage reaches the static gain, the first decay rate is again selected.

61. An audio apparatus including a signal processing circuit as claimed in claim 1.

62. Audio apparatus as claimed in claim 61 in portable form.

63. A communications apparatus incorporating audio apparatus according to claim 61.

64. An in-car audio apparatus incorporating audio apparatus according to claim 61.

65. A headphone apparatus incorporating audio apparatus according to claim 61.

66. A stereo headphone apparatus incorporating audio apparatus according to claim 61.

67. An audio apparatus according to claim 61 further including an audio output transducer connected as a load connected to an output terminal of said signal processing circuit.
